(19) United States
(12) Patent Application Publication
(10) Pub. No.: US 2012/0052244 A1
(43) Pub. Date: Mar. 1, 2012

(54) LAYER SYSTEM HAVING BARRIER PROPERTIES AND A STRUCTURED CONDUCTIVE LAYER, METHOD FOR PRODUCING THE SAME, AND USE OF SUCH A LAYER SYSTEM

(75) Inventors: Waldemar Schoenberger, Dresden (DE); Matthias Fahland, Dresden (DE); John Fahlteich, Dresden (DE); Ulrich Todt, Moritzburg (DE); Christian Kirchhof, Dresden (DE)

(73) Assignee: FRAUNHOFER-GESELLSCHAFT ZUR FOERDERUNG DER ANGEWANDTEN FORSCHUNG E.V., Muenchen (DE)

(21) Appl. No.: 13/319,002

(22) PCT Filed: Apr. 29, 2010
(86) PCT No.: PCT/EP2010/002637

§ 371 Date: Nov. 4, 2011

(30) Foreign Application Priority Data
May 5, 2009 (DE) 10 2009 019 951.9

(51) Int. Cl. B32B 3/00; H05K 13/00

(52) U.S. Cl. 428/141; 216/13

(57) ABSTRACT

The invention relates to a layer system, comprising a substrate (1) on which firstly at least one barrier layer (2), followed by an intermediate layer (3) acting as an etch-stop layer and subsequently at least one electrically conductive layer (4) are deposited, and wherein the electrically conductive layer (4) is structured with wet-chemical etching media. The invention further relates to a method for the production and uses of a layer system of this type.

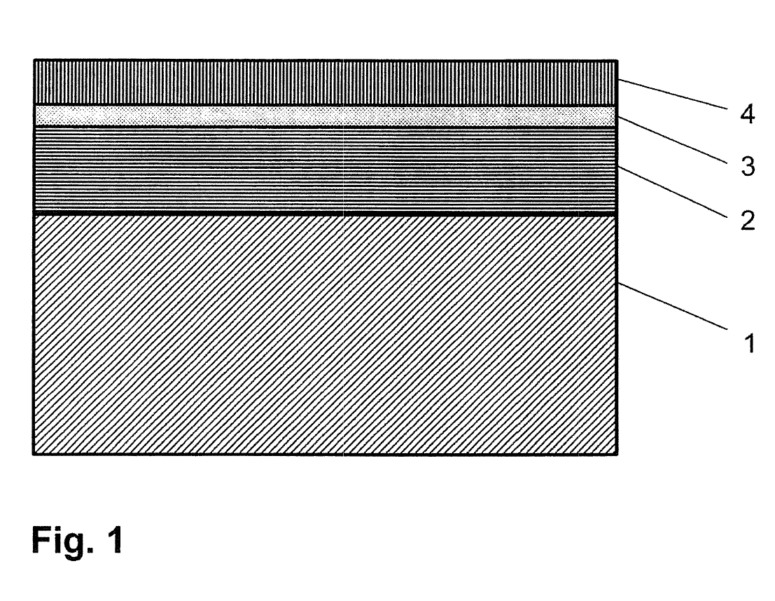

The invention relates to a layer system, which comprises a substrate, a barrier layer and a structured, electrically conductive layer, wherein the barrier layer exerts a blocking effect with respect to water vapor and oxygen. Furthermore, the invention discloses a method for producing and uses of such a layer system.

If no additional information is provided on the temperature and relative air humidity, the term “water vapor permeability” (WVP for short) below is to be understood to mean the water vapor permeability measured at 23° C. and 85% relative air humidity and the term “oxygen permeability” (OP for short) is to be understood to mean the oxygen permeability measured at 23° C. and 0% relative air humidity.

The term “barrier layer” characterizes below and with respect to a layer system according to the invention a layer which deposited on a substrate has a WVP<1 g/(m² d) and an OP<3 cm³/(m² d bar). Barrier layers are principally used to reduce the permeation of water vapor, oxygen and optionally further substances. Sensitive goods or materials can be protected by the action of a barrier layer (also referred to below as a permeation barrier). Thus, for example, the use of plastic films with a barrier layer located thereon is very widespread as a packaging film for foodstuffs.

### PRIOR ART

It is known that a barrier layer can be embodied as an individual layer or as a layer system (composed of several layers or partial layers) (DE 10 2004 005 313 A1 or DE 10 2004 061 464 B4). Barrier layers can also comprise a hybrid polymer as a layer material, as is described in DE 196 50 286 C2, for example. Such a hybrid polymer is a material which is composed of a network of organic and inorganic substances. A hybrid polymer is known, for example, from WO 92/16571 A1 or under the name of ORMOCERe®.

Plastic films are often used as a substrate for a barrier layer. The term “barrier film” below relates to a layer system which comprises at least one plastic film and at least one barrier layer deposited thereon. A barrier film of this kind, for example can be used as a packaging material or as an encapsulation film. In addition to a substrate and a barrier layer, a barrier film can also comprise further layers, however, such as for example adhesion promoter layers or optical adjustment layers or functional layers (for example, UV blocker layers or AR layers).

A requirement often lies in that a barrier layer should not only form a permeation barrier, but at the same time should also be optically transparent. Optical transparency means here that the barrier layer has a sufficiently high transmission in a desired, in particular visible, wavelength range of light. There is a requirement for transparency in the visible spectral range in particular when a barrier layer or a barrier film is to be used for the encapsulation of solar cells or OLEDs. The layer structure for a transparent barrier film is described, for example, in DE 10 2007 019 994 A1.

In the case of various components, for example with flexible solar cells that are to be encapsulated with a barrier film or with which a barrier film acts as a substrate, in addition to a barrier layer, an electrically conductive layer as an electrode is also needed. An electrically conductive layer below means a layer (also referred to as an electrode layer), which has a sheet resistance R^{□} of less than 1000Ω/□.

In many cases an electrode layer should also have a high optical transparency. The term of a transparent electrode layer (or transparent electrode for short) below relates to a layer which with a transmission of >60% in the visible wavelength range of light has a sheet resistance R^{□} of less than 1000Ω/□. In many applications, even a sheet resistance R^{□} of less than 100Ω/□ with an optical transmission of at least 70% or more is required.

A mixed oxide composed of In₂O₃ and SnO₂, so-called ITO (indium tin oxide), for example, is suitable as a layer material for transparent electrode layers. However, other materials are known which have the property of being able to conduct electric current with a good transparency in the visible range. ZnOₓ with an Al, Ga or Si doping (ZnOAl or ZOA, ZnOGa, ZnOSi) can be cited as an example of this. Transparent conductive oxides of this type are also referred to as TCO (Transparent Conductive Oxides).

Through a combination of a barrier layer and an electrode layer on a substrate, the functionalities of permeation barrier and conductivity can also be combined. For the functionality of an electrode layer, however, it is often necessary to structure the electrode surface. This can be carried out in different ways.

Methods for structuring TCO layers on glass as a substrate material are already known. If glass is used as a substrate, no separate barrier layer is necessary under the TCO layer, because the glass substrate already has the necessary barrier properties. It is known from EP 0 322 258 A2 that the structuring of an ITO layer located on a glass substrate can be realized by means of a laser. In the attempt to apply the method to a barrier film with a transparent electrode layer, it was ascertained that the laser during structuring also damages the barrier layer and thus substantially reduces the barrier effect.

In the case of transparent electrode layers, this effect is produced among other things by the similarity of the TCO layer and the barrier layer with respect to their optical properties in the range of the wavelength of the laser used. Thus not only the electrode layer, but also the barrier layer is ablated by the laser. In addition problems arise due to the residues (debris), which are left behind after a laser application and must be removed before the assembly of the components.

Further widespread structuring methods known above all from the field of electronics (e.g., lift-off, mechanical structuring) have similar disadvantages or are ruled out from the start due to a restricted applicable temperature range because of the properties of a plastic film.

Wet-chemical etching is known as a very flexible method for producing layer structures. Here a chemically aggressive medium is applied in the shape of the desired structure on the surface of a layer to be structured. By means of a chemical reaction, the material of the layer to be structured is shifted into a state in which it can be removed with a suitable method.

WO 2008/052637 A1 describes a printable, dispersible etching medium for etching TCO layers, which is used for structuring ITO on glass substrates. After the application and the processing of the etching medium, the TCO layer can be rinsed away by water in those surface areas in which the etching medium was applied. Although the layer systems created in this manner have good barrier properties and also have a structured, electrically conductive layer, they are not suitable for use with flexible solar cells or OLEDs due to the rigid glass substrate.

### OBJECT

The object of the invention is therefore to create a layer system that overcomes the disadvantages of the prior art. In particular, the layer system should have good barrier properties with respect to water vapor and oxygen as well as comprising a structured, electrically conductive layer. The layer system should likewise also be able to comprise a flexible plastic film as a substrate and also be embodied to be transparent in the visible wavelength range of light. Another object of the invention is to disclose a method for the production and a use of a layer system of this type. It should also be possible to produce the layer system by means of a so-called roller-to-roller method.

The technical object is attained by the subject matters with the features of claims 1 and 10. Further advantageous embodiments of the invention are shown by the dependent claims.

A layer system according to the invention comprises a substrate, on which at least one barrier layer and at least one electrically conductive layer are deposited, wherein the barrier layer is located between the substrate and the electrically conductive layer. The electrically conductive layer is thereby structured by means of wet-chemical etching processes, without impairing the barrier properties of the layer system. This is possible because with a layer system according to the invention, an intermediate layer is also deposited between the barrier layer and the electrically conductive layer, which intermediate layer acts as an etch-stop layer and thus protects the barrier layer during the wet-chemical structuring of the electrically conductive layer. Without the intermediate layer, the barrier layer could also be chemically attacked during the etching process, which would have a negative effect on the barrier properties of the layer system.

With respect to the operating method, in the case of such an intermediate layer acting as an etch-stop layer, a distinction can be made between two types.

On the one hand the intermediate layer can be embodied as a so-called sacrificial layer. This means that the intermediate layer during the etching process like the electrically conductive layer is chemically changed by the etching medium and therefore during the etching process is removed at least in an upper layer thickness region. The intermediate layer embodied as a sacrificial layer is so thick, however, that the etching medium does not have an etching or layer-removing effect on the barrier layer lying beneath. Silicon oxides (SiOₓ) or silicon oxides with carbon content (SiOₓC_{y}) in a layer thickness range of 20 nm to 300 nm, for example, are suitable as layer materials for a sacrificial layer of this type. Layer thicknesses of even 20 nm to 100 nm are often sufficient for embodying a sacrificial layer.

On the other hand, the intermediate layer can also be composed of such materials that are at least largely resistant to an etching medium used, so that during the etching process no layer material or only a little layer material is removed from the intermediate layer. This embodiment has the advantage that such an etching-resistant intermediate layer can be embodied with a smaller thickness than a sacrificial layer.

The substrate of a layer system according to the invention can also be composed of a plastic, for example, in addition to glass or a ceramic material. It is particularly advantageous when the substrate is embodied as a flexible plastic film. Then due to its flexibility, the layer system can also be used in the encapsulation of components or to assemble components on the layer system, for example. Furthermore, a plastic film as a substrate results at the same time in a reduction in weight compared to other materials, such as glass or ceramic, for example.

In one embodiment at least one layer of the layer system is embodied to be transparent in the visible wavelength range. Thus it can be expedient for example, in the case of an electrically conductive layer that is not embodied to be transparent, to embody the barrier layer of the layer system to be transparent, if the barrier layer is to have an electrically insulating effect at the same time. This type of embodiment with non-transparent electrically conductive layer and transparent barrier layer is also advantageous, for example, when a light incidence occurs from the substrate side and the electrically conductive layer at the same time is to have a light-reflecting effect.

If the entire layer system is embodied to be transparent in the visible wavelength range, the layer system can also be used in the production of solar cells or OLEDs. In a further embodiment, at least one layer of the layer system is transparent in the infrared wavelength range. This is also advantageous for the use with OLEDs, for example, since they also operate in the infrared wavelength range to an increasing extent. A transparency is in particular suitable hereby in a wavelength range up to 2 μm.

If a layer of the layer system comprises an oxide, in a reactive deposition method, the transparency of this layer can be adjusted, for example, via the oxygen inflow quantity into the vacuum chamber.

All layers can be used as a barrier layer of which layers a barrier effect of the type defined above is also known in the prior art. A barrier layer of a layer system according to the invention can thus also be embodied as an individual layer or as a composite of at least two partial layers.

In a further embodiment, the barrier layer comprises at least two inorganic partial layers, between which an organic partial layer is arranged. For example, at least one of the inorganic partial layers can comprise a mixed oxide of the elements zinc and tin hereby. The organic partial layer can be composed for example of a hybrid polymer. Alternatively, the barrier layer can also be embodied as a single layer and comprise zinc tin oxide as a layer material. Layers of zinc tin oxide have very good barrier properties with respect to water vapor and oxygen.

Various materials are suitable for the intermediate layer or etch-stop layer. Thus the intermediate layer can comprise a compound of the elements silicon and oxygen or a compound of the elements silicon, nitrogen and oxygen, for example. Compounds of the elements silicon, oxygen and carbon are also suitable for this purpose. Layers of this type can be advantageously deposited by means of PECVD methods with high coating rates. If a magnetron is thereby used as a plasma source, a good compatibility of the process at other coating stations of a sputtering installation can be achieved at the same time. Zirconium oxide is particularly suitable as a layer material for the intermediate layer, because this material has a good resistance to known etching media. To deposit this layer material, reactive magnetron sputtering is preferably used, because high coating rates and very good layer thickness uniformities are achieved therewith.

The intermediate layer of a layer system according to the invention is to be embodied with a layer thickness in a range of 10 nm to 300 nm. From 10 nm layer thickness for the intermediate layer, a good protection for the barrier layer lying beneath is already achieved in structuring the electrically conductive layer, so that the barrier properties of the barrier layer are largely retained. Although a layer with a still larger layer thickness than 300 nm also fulfils the purpose of an etch-stop layer, it is not necessary for this purpose and has only an adverse effect regarding the flexibility of the layer system.

A layer thickness in the range of 20 nm to 200 nm is particularly suitable for the intermediate layer. Layer thicknesses in a range of 40 nm to 100 nm are particularly suitable. A very good protection of the barrier layer beneath is achieved in this layer thickness range. Moreover, in this thickness range intermediate layers with a high transparency can be realized.

All materials that are also used in the prior art for electrically conductive layers can also likewise be used as a material for the electrically conductive layer. Conductive oxides, such as ITO, are particularly suitable for this purpose, because conductive oxides can also be deposited in transparent form.

A method according to the invention for producing a layer system according to the invention is characterized in that firstly at least one barrier layer, then an intermediate layer acting as an etch-stop layer, followed by at least one electrically conductive layer are deposited on a substrate and that subsequently the electrically conductive layer is structured with the aid of wet-chemical etching media.

Media such as are described in WO 2008/052637 A1 can be used as etching media, for instance. The entire process step of structuring or etching the electrically conductive layer can be carried out according to WO 2008/052637 A1, for example, the entire disclosure of which in this respect is incorporated herein by reference.

The barrier layer can be deposited as an individual layer or also in the form of at least two partial layers, wherein the individual layer or at least one of the partial layers can be deposited by means of a PECVD process. It is advantageous hereby if a magnetron is used as a plasma source, because layers with very good barrier properties can be deposited by means of magnetron PECVD methods. A unipolar pulse magnetron or also a double magnetron operated at a medium frequency can be used as a magnetron.

Magnetron sputtering methods in general and reactive magnetron sputtering methods specifically as well as PECVD methods, including magnetron PECVD methods are suitable for depositing the intermediate layer.

The electrically conductive layer can likewise be applied by means of all of the vacuum methods for depositing an electrically conductive layer known from the prior art.

When using a flexible substrate, it is therefore possible to deposit the barrier layer, the intermediate layer as well as the electrically conductive layer consecutively and without vacuum interruption by means of a roller-to-roller method. Even the structuring of the electrically conductive layer, which is carried out at atmospheric pressure, however, can be integrated into the roller-to-roller process.

### EXEMPLARY EMBODIMENT

The invention is explained in more detail below based on a preferred exemplary embodiment. The only FIGURE shows a diagrammatic representation of a layer system according to the invention in cross section.

A flexible and transparent plastic film of polyethylene terephthalate (PET) with a thickness of 75 μm and a water vapor permeability of 7.9 g/(m²d) was used as substrate 1 for the layer system according to the invention. With a reactive sputtering process by means of a medium-frequency pulsed double magnetron, a layer 2, 200 nm thick and transparent, of zinc tin oxide was deposited on the substrate 1 inside a vacuum chamber. Alloying targets, composed of zinc and tin in a ratio of 52:48 were atomized in an argon oxygen gas mixture hereby. The partial pressure of oxygen inside the vacuum chamber was measured via optical plasma emission and kept constant over the coating period at a value of 150 sccm by means of a regulating system, with which the oxygen inflow quantity into the vacuum chamber was adjusted.

A water vapor permeability of 0.01 g/(m²d), measured at 38° C. and 90% relative air humidity, was determined for the layer composite, composed of substrate 1 and layer 2. The layer 2 thus acts as a barrier layer with very good barrier properties with respect to water vapor.

Subsequently, a transparent layer 3, 60 nm thick, was deposited on the barrier layer 2 by means of a magnetron PECVD process, for which the gases argon and oxygen as well as the precursor HMDSO in gas phase were introduced into the vacuum chamber. The molecules of the gas mixture produced thereby were activated by means of a magnetron plasma and chemical reactions were caused thereby, which lead to the layer deposition. The magnetron plasma was formed thereby in that a double magnetron equipped with titanium targets was operated at a frequency of 40 kHz pulsed in a bipolar manner. The process parameters were adjusted such that the lowest possible sputtering removal occurs at the titanium targets. The double magnetron was therefore operated only for the purpose of generating a plasma. However, it was not intended to make a direct contribution to the layer structure by atomizing the titanium targets. As a result of the magnetron PECVD method, the layer 3 of silicon oxide with carbon compounds (SiOₓC_{y}) was produced. That is, the layer 3 has inorganic as well as organic layer constituents, which are linked to one another at the molecular level.

A transparent and electrically conductive layer 4, 100 nm thick, of ITO with a sheet resistance R^{□} of 50Ω□, which was deposited by means of a DC-operated single magnetron, is still located on the layer 3. A ceramic ITO target was used as target material and, in addition to the working gas argon, a small amount of oxygen (6 sccm) was also introduced into the vacuum chamber, whereby an optimal layer stoichiometry was achieved, which is necessary to achieve the desired layer resistance.

In a final process step the structuring of the electrically conductive layer 4 took place. The resist paste used for this purpose has the features as they are described in WO 2008/052637 A1. The resist paste was applied on the surface of the electrically conductive layer 4, in the regions in which the electrically conductive layer was to be removed, and after an exposure time was rinsed off with water. As a result of this a structured electrically conductive layer 4 was produced with layer regions electrically insulated from one another, which can be used as an electrode, for example.

After the structuring of the electrically conductive layer 4, the same value regarding the water vapor permeability of the layer system composed of substrate 1 and layers 2 through 4 was determined as was previously measured in the substrate 1 coated only with the barrier layer 2, which means that the layer 3 had been effective as an etch-stop layer and thus protected the barrier layer lying beneath completely from an etching action during the structuring of the electrically conductive layer 4.

We therefore have a flexible and transparent layer system, which comprises very good barrier properties and a structured, electrically conductive layer. A layer system of this type according to the invention can be used, for example, as a base substrate for the structure of optical components or can be applied for the purpose of encapsulation and subsequent interconnection on components already produced. Due to the transparency of the layer system of 75%, averaged over the visible wavelength range of light, this can also be used with components such as solar cells and OLEDs.

The realization of the layer structure shown, with the given process steps, can be carried out in an in-line process in which the layers comprised by the layer system are applied sequentially. This makes it possible to implement the entire production process of the layer system in a roller-to-roller process in vacuum, since the structuring of the electrically conductive layer can also be carried out in a roller-to-roller process under atmospheric pressure, which is an important economic advantage.

1. A layer system, comprising a substrate (1), on which firstly at least one barrier layer (2), followed by an intermediate layer (3) acting as an etch-stop layer, and subsequently at least one electrically conductive layer (4) are deposited and wherein the electrically conductive layer (4) is structured with the aid of wet-chemical etching media.

2. The layer system according to claim 1, characterized in that the substrate (1) and/or the barrier layer (2) and/or the intermediate layer (3) and/or the electrically conductive layer (4) is/are embodied to be transparent to light in the visible wavelength range and/or transparent in the infrared wavelength range.

3. The layer system according to claim 1, characterized in that the intermediate layer is composed of a compound of at least two elements from the group silicon, oxygen, nitrogen, zirconium, carbon.

4. The layer system according to claim 1, characterized in that the thickness of the intermediate layer (3) is adjusted in a range of 10 nm to 300 nm, preferably in a range of 20 nm to 200 nm and very preferably in a range of 40 nm to 100 nm.

5. The layer system according to claim 1, characterized in that the barrier layer is composed of at least two partial layers.

6. The layer system according to claim 5, characterized in that the barrier layer comprises two inorganic partial layers, between which an organic partial layer, which is preferably embodied as a hybrid polymer, is embedded.

7. The layer system according to claim 6, characterized in that at least one of the two inorganic partial layers comprises a mixed oxide of the elements zinc and tin.

8. The layer system according to claim 1, characterized in that the substrate is embodied as a plastic film.

9. The layer system according to claim 1, characterized in that the electrically conductive layer is composed of ITO.

10. A method for producing a layer system according claim 1, wherein firstly at least one barrier layer (2), then an intermediate layer (3) acting as an etch-stop layer, followed by at least one electrically conductive layer (4) are deposited on a substrate (1) and wherein finally the electrically conductive layer (4) is structured with the aid of wet-chemical etching media.

11. The method according to claim 10, characterized in that the intermediate layer is deposited by means of reactive magnetron sputtering.

12. The method according to claim 10, characterized in that the intermediate layer is deposited by means of a PECVD process, in which a magnetron is used as a plasma source.

13. The method according to claim 10, characterized in that the barrier layer is deposited in the form of at least two partial layers, wherein at least one of the partial layers is deposited by means of a PECVD process, in which a magnetron is used as a plasma source.

14. The method according to claim 12, characterized in that a unipolar pulsed magnetron or a double magnetron operated at a medium frequency is used as a magnetron.

15. The method according to claim 10, characterized in that the barrier layer, the intermediate layer and the electrically conductive layer are deposited successively on a continuously moved plastic film, without an intermediate stop of the plastic film.

16. The layer system according to claim 1, characterized in that this a) is used as a substrate for the construction of optical components or b) is applied onto components already produced for the purpose of encapsulation and/or final interconnection.
